(19) United States
(12) Patent Application Publication
(10) Pub. No.: US 2023/0222259 A1
(43) Pub. Date: Jul. 13, 2023

(54) SPATIAL DESIGN SYSTEM, SPATIAL DESIGN METHOD, AND PROGRAM

(71) Applicant: Panasonic Intellectual Property Management Co., Ltd., Tokyo (JP)

(72) Inventors: Ayumi SAKAI, Osaka (JP); Yuya SHIRASAKA, Osaka (JP)

(21) Appl. No.: 17/795,486

(22) PCT Filed: Jan. 13, 2021
(86) PCT No.: PCT/JP2021/000911

§ 371 Date: Jul. 26, 2022

(30) Foreign Application Priority Data
Jan. 31, 2020 (JP) 2020-015861

(51) Int. Cl. G06F 30/20; G06F 30/13

(52) U.S. Cl. CPC G06F 30/20; G06F 30/13

(57) ABSTRACT

A spatial design system includes an acquirer, a generator, and a design information outputter. The acquirer is configured to acquire layout information on a space in a facility, environment information on an environment to be controlled in the space, and a target value of an effect which a person in the space is to obtain from a space design for the space. The generator is configured to acquire, based on the layout information, the environment information, and the target values, planting design information on a design for a plant to be arranged in the space. The design information outputter is configured to output the planting design information.

### TECHNICAL FIELD

The present disclosure generally relates to spatial design systems, spatial design methods, and programs and specifically relates to a spatial design system, a spatial design method, and a program which are configured to produce a design for a plant to be arranged in a space.

### BACKGROUND ART

A system is known which is configured to green an optimal housing environment (space in a facility) in accordance with wishes of residents (see Patent Literature 1).

Patent Literature 1 discloses a system including: a database storing a variety of information on houseplants by plant species; an inputter via which a user inputs a condition and the like for a housing environment, selects at least one houseplant in the database, and virtually arranges the at least one houseplant in a room; a processor configured to quantify, based on the variety of information stored in the database, a warmth comfort effect, a relaxing effect, an air purification effect, and a virtual effect and an imagery effect that relieve or reverse visual fatigue when the at least one houseplant is virtually arranged in the housing environment for which the condition has been specified; and an outputter configured to visually output each of the effects thus quantified.

### CITATION LIST

### Patent Literature

Patent Literature 1: JP 2010-172305 A

### SUMMARY OF INVENTION

In the system disclosed in Patent Literature 1, a user selects a houseplant (plant) and virtually arranges the houseplant in a room (in a space), and thereby, an effect to be obtained by the user is visualized and output. If the effect (a numerical value) thus visualized and output is not a numerical value expected by the user, the user has to repeatedly perform an operation of selecting a houseplant (plant) and virtually arranging the houseplant in the room (the space) (an operation of producing a planting design) until the effect visualized and output is the numerical value expected by the user. Thus, providing a suggestion about a planting design according to an expected effect is desirable.

In view of the foregoing, it is an object of the present disclosure to provide a spatial design system, a spatial design method, and a program which are configured to provide a planting design according to an effect expected by a user.

A spatial design system according to an aspect of the present disclosure includes an acquirer, a generator, and a design information outputter. The acquirer is configured to acquire layout information on a space in a facility, environment information on an environment in the space, and a target value of an effect which a person in the space is to obtain from a space design for the space. The generator is configured to generate, based on the layout information, the environment information, and the target value, planting design information on a design for a plant to be arranged in the space. The design information outputter is configured to output the planting design information.

The spatial design method according to an aspect of the present disclosure includes a first acquisition step, a second acquisition step, and a design information output step. The first acquisition step includes acquiring layout information on a space in a facility, environment information on an environment in the space, and a target value of an effect which a person in the space is to obtain from a space design for the space. The second acquisition step includes generating, based on the layout information, the environment information, and the target value, planting design information on a design for a plant to be arranged in the space. The design information output step includes outputting the planting design information.

A program according to an aspect of the present disclosure is a program configured to cause a computer to execute the spatial design method.

### BRIEF DESCRIPTION OF DRAWINGS

FIG. 1 is a block diagram of the configuration of a spatial design device as a spatial design system according to an aspect;

FIG. 2 is a view illustrating operation of the spatial design device; and

FIG. 3 is a view illustrating operation when the spatial design device receives layout information.

### DESCRIPTION OF EMBODIMENTS

An embodiment and variations described below are mere examples of the present disclosure, and the present disclosure is not limited to the embodiment and the variations. Various modifications may be made to embodiments other than the embodiment and the variations below depending on design and the like within the scope of the technical idea of the present disclosure.

### Embodiment

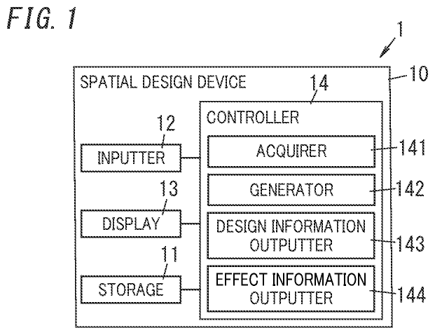

A spatial design system 1 and a spatial design method according to the present embodiment will be described below with reference to FIGS. 1 to 3.

(1) Overview

A spatial design device 10 as the spatial design system 1 of the present embodiment suggests an arrangement and an amount of a plant(s), and a plant species (type(s) of the plant(s)) such that a person in a space (one room) of a facility can obtain a more appropriate effect.

Examples of the “facility” mentioned in the present disclosure include: non-dwelling facilities such as offices, shops, business establishments, factories, buildings, schools, welfare facilities, and hospitals; and dwelling facilities such as detached dwelling houses, multiple residential dwelling complexes, and dwelling units of multiple residential dwelling complexes. Examples of such non-dwelling facilities include theaters, movie theaters, public halls, amusement facilities, complex facilities, restaurants, department stores, hotels, inns, kindergartens, libraries, museums, art museums, underground shopping malls, railway stations, and airports. The examples of the “facility” as mentioned in the present disclosure further include outdoor facilities such as ballparks, gardens, parking lots, athletic grounds, and parks.

Moreover, the “effect” as mentioned in the present disclosure includes at least one of a comfort effect, a fatigue relaxation effect, or an impression effect. In the present embodiment, the “effect” includes the comfort effect, the fatigue relaxation effect, and the impression effect. Here, the comfort effect includes the degree of relaxation, the degree of a stress reduction, and the like which a person in the space of the facility obtains. The fatigue relaxation effect includes the degree of fatigue relaxation which the person in the space of the facility obtains. The impression effect includes gorgeousness, neatness, openness, refreshment, and the like which the person in the space of the facility obtains from the space.

The spatial design device 10 acquires layout information on the space in the facility, environment information on an environment in the space, and target values of the effects which a person in the space is to obtain from a space design for the space. The spatial design device 10 acquires, based on the layout information, the environment information, and the target values, planting design information on a design for a plant to be arranged in the space. The spatial design device 10 outputs the planting design information.

Moreover, the spatial design device 10 outputs, based on the planting design information, effect information on the effects which the person in the space is to obtain from the space.

Here, the environment information includes at least one of temperature information on temperature, humidity information on humidity, light information on light, or sound information on sound in the space.

(2) Configuration

As shown in FIG. 1, the spatial design device 10 of the present embodiment includes a storage 11, an inputter 12, a display 13, and a controller 14.

The spatial design device 10 includes, for example, a computer system including a processor and memory. The processor executes a program stored in the memory, and thereby, the computer system functions as the controller 14. In this embodiment, the program to be executed by the processor is stored in advance in the memory of the computer system. However, this is only an example and should not be construed as limiting. The program may also be distributed after having been stored in a non-transitory storage medium such as a memory card or downloaded via a telecommunications network such as the Internet.

The storage 11 includes a device selected from, for example, read only memory (ROM), random access memory (RAM), electrically erasable programmable read only memory (EEPROM), and the like.

The storage 11 stores, regarding a plurality of plants as options to be arranged in the space of the facility, feature amount data pieces according to the effects which the person in the space is to obtain from the space for each of the types of the plants (plant species). The feature amount data pieces as used herein are data pieces (scores) obtained by quantifying the effects which the person in the space is to obtain from the space. The feature amount data pieces include a score according to the comfort effect (comfort score), a score according to the fatigue relaxation effect (fatigue relaxation score), and a score according to the impression effect (impression score).

The storage 11 stores, regarding the plurality of plants, pieces of constituent element information on constituent elements of each of the plants. The pieces of constituent element information as used herein include the color of leaves of a corresponding one of the plants, whether or not the leaves have patterns, the shape of the leaves, the number of colors of the leaves, and whether or not the leaves include at least one accent leaf.

The inputter 12 receives an input of the layout information on the space in the facility, the environment information on the environment in the space, and the target values of the effects which the person in the space is to obtain from the space design for the space.

The layout information as used herein includes information on a planned plant-arrangement location and information on a location where a person is present in a space. For example, in the case of the facility being an office, the inputter 12 receives, as the layout information, information including pieces of information on arrangement locations of desks, planned plant-arrangement locations, and presence locations of people in the space.

The environment information includes a temperature set in the space of the facility as the temperature information, a humidity set in the space of the facility as the humidity information, illuminance or the quantity of light set in an illumination in the space of the facility as the light information, and stream of natural sound, music, sound volume, or a combination thereof in the space of the facility as the sound information. Note that the environment information may include both the illuminance and the quantity of light as the light information.

The target values include a target value for the comfort effect (comfort target value), a target value for the fatigue relaxation effect (fatigue relaxation target value), and a target value for the impression effect (impression target value). Each of the comfort target value, the fatigue relaxation target value, and the impression target value is represented by, for example, any one of integers 1 to 5. That is, an acquirer 141 receives any one of integers 1 to 5 as each of the comfort target value, the fatigue relaxation target value, and the impression target value.

The inputter 12 may receive the layout information, the environment information, and target values of the effects from an input device such as a keyboard, a mouse, or a scanner, or another terminal (e.g., an information appliance such as a tablet computer or a smartphone) by communication such as wireless communication.

The display 13 is implemented as a thin display device such as a liquid crystal display or an organic electroluminescence (EL) display. The display 13 displays a screen (first screen) based on the planting design information. The display 13 further displays a screen (second screen) based on the effect information. In the first screen, an arrangement location(s), the amount, and a plant species(s) of a plant(s) to be arranged in the space are presented. In the second screen, the comfort effect, the fatigue relaxation effect, and the impression effect which the person is to obtain from the space by the arrangement location(s), the amount, and the plant species(s) of the plant(s) displayed in the first screen are presented in quantity.

As shown in FIG. 1, the controller 14 includes the acquirer 141, a generator 142, a design information outputter 143, and an effect information outputter 144.

The acquirer 141 acquires the layout information on the space in the facility, the environment information on the environment in the space, and the target values of the effects which the person in the space is to obtain from the space design for the space. Specifically, the acquirer 141 acquires the layout information, the environment information, and the target values of the effects (the comfort target value, the fatigue relaxation target value, and the impression target value) via the inputter 12.

The generator 142 generates, based on the layout information, the environment information, and the target values, the planting design information.

The generator 142 acquires, in accordance with Expression 1 “Y1=F1 (X (amount), X (arrangement), X (plant species), X (temperature), X (humidity), X (illuminance), . . . )” for obtaining the comfort effect, Expression 2 “Y2=F2 (X (amount), X (arrangement), X (plant species), X (temperature), X (humidity), X (illuminance), . . . )” for obtaining the fatigue relaxation effect, and Expression 3 “Y3=F3 (X (amount), X (arrangement), X (plant species), X (temperature), X (humidity), X (illuminance), . . . )” for obtaining the impression effect, the planting design information according to the target values acquired by the acquirer 141. X (amount) is a variable of the amount of a plant. X (arrangement) is a variable of the arrangement of the plant. X (plant species) is a variable of the plant species. X (temperature) is a variable of the temperature. X (humidity) is a variable of the humidity. X (illuminance) is a variable of the illuminance of an illumination. Here, the variable “X (arrangement)” may include two variables of the location of the person and the distance to the plant.

The generator 142 assigns the comfort target value to the variable Y1 and assigns the temperature, the humidity, the illuminance, and the like included in the environment information respectively to the variables X (temperature), X (humidity), X (illuminance), and the like of Expression 1. The generator 142 assigns the fatigue relaxation target value to the variable Y2 and assigns the temperature, the humidity, the illuminance, and the like included in the environment information respectively to the variables X (temperature), X (humidity), X (illuminance), and the like of Expression 2. The generator 142 assigns the impression target value to the variable Y3 and assigns the temperature, the humidity, the illuminance, and the like included in the environment information respectively to the variables X (temperature), X (humidity), X (illuminance), and the like of Expression 3.

The generator 142 calculates one or more combinations of solutions including X (amount), X (arrangement), and X (plant species) in accordance with Expressions 1 to 3 to which the respective values are assigned.

The generator 142 calculates, for the expression for each of the comfort target value, the fatigue relaxation target value, and the impression target value, one or more combinations of solutions by changing the value of each of the variables X (amount), X (arrangement), and X (plant species) by 0.1.

When regarding the variable “X (arrangement)” of each combination thus calculated, a difference of the distance between the person and the plant from the distance between the location of the person and the planned plant-arrangement location included in the layout information is a prescribed value or greater, the generator 142 excludes such a combination from the combinations of solutions.

The generator 142 acquires, from the storage 11, one or more plant species for which the comfort target value corresponds to the comfort score, the fatigue relaxation target value corresponds to the fatigue relaxation score, and the impression target value corresponds to the impression score.

The generator 142 generates (acquires), as the planting design information, each of one or more combinations of solutions including any one of: one or more plant species acquired based on the comfort target value; one or more plant species acquired based on the fatigue relaxation target value; or one or more plant species acquired based on the impression target value of the remaining one or more combinations of solutions. Thus, the generator 142 can generate (acquire) the planting design information for a plant corresponding to feature amount data piece complying with the target value of the feature amount data pieces for each of the types of the plants.

The generator 142 calculates, for each of the pieces of planting design information thus generated, the comfort effect, the fatigue relaxation effect, and the impression effect by using a corresponding one of the pieces of planting design information and Expressions 1 to 3.

The design information outputter 143 outputs the planting design information. Specifically, the design information outputter 143 outputs at least one piece of planting design information of one or more pieces of planting design information acquired by the generator 142 to the display 13.

For example, the design information outputter 143 outputs, to the display 13, planting design information, in which difference values of the comfort effect, the fatigue relaxation effect, and the impression effect, which are obtainable from each piece of planting design information, respectively from the comfort target value, the fatigue relaxation target value, and the impression target value are minimum, of the one or more pieces of planting design information. Note that when the one or more pieces of planting design information includes a plurality of pieces of planting design information in which the difference values are minimum, all of the plurality of pieces of planting design information in which the difference values are minimum are output to the display 13.

The effect information outputter 144 outputs, based on the planting design information, the effect information on the effects which the person in the space is to obtain from the space. Specifically, the effect information outputter 144 outputs, as the effect information to the display 13, information including the comfort effect, the fatigue relaxation effect, and the impression effect obtainable based on the planting design information output from the design information outputter 143.

(3) Operation

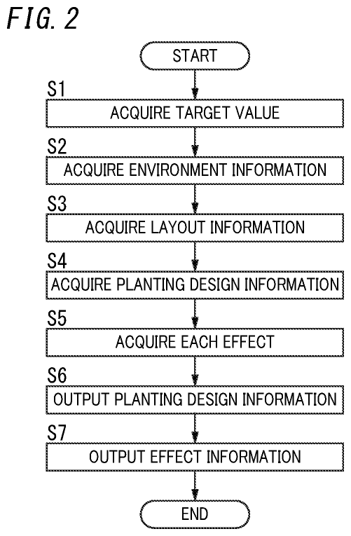

The operation of the spatial design device 10 is now described with reference to FIG. 2.

The acquirer 141 acquires the target value of the effect via the inputter 12 (step S1). Here, the target value includes the comfort target value, the fatigue relaxation target value, and the impression target value.

The acquirer 141 acquires the environment information via the inputter 12 (step S2). Here, the environment information includes information on a temperature and a humidity set in the space of the facility, the illuminance or the quantity of light set in the illumination in the space of the facility, and a sound in the space.

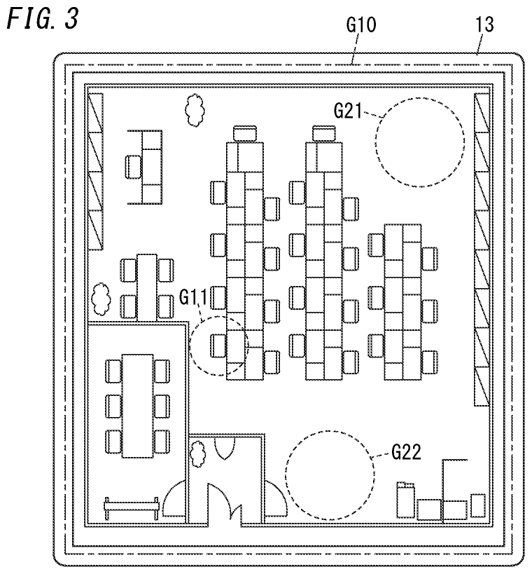

The acquirer 141 acquires the layout information via the inputter 12 (step S3). For example, the acquirer 141 acquires a layout plan representing arrangement locations of desks and the like in the space. The acquirer 141 causes an arrangement screen G10 presenting the layout plan to be displayed by the display 13 (see FIG. 3). A user gives an operation via a keyboard, a mouse, or the like to the arrangement screen G10 to specify a presence location G11 where the person is present and planned plant-arrangement locations G21 and G22. The acquirer 141 acquires coordinates representing areas of the presence location G11 and the planned plant-arrangement locations G21 and G22 thus specified. Thus, the acquirer 141 can acquire the layout information including information on each of the arrangement locations of the desks, the planned plant-arrangement location, and the presence location of the person in the space.

The generator 142 acquires the planting design information with reference to the layout information, the environment information, and the target value (step S4). The generator 142 acquires, based on Expressions 1 to 3, the planting design information according to the target value acquired by the acquirer 141.

Specifically, the generator 142 calculates one or more combinations of solutions for the expression for each of the comfort target value, the fatigue relaxation target value, and the impression target value by changing the value of each of the variables X (amount), X (arrangement), and X (plant species) by 0.1. When regarding the variable “X (arrangement)” of the one or more combinations of solutions thus calculated, the distance between the person and the plant differs from the distance between the location of the person and the planned plant-arrangement location included in the layout information by a prescribed value or greater, the generator 142 excludes such (a) combination(s) from the combinations of solutions. The generator 142 acquires (extracts), as the planting design information, each of one or more combinations of solutions including any one of one or more plant species acquired based on the respective target values and the respective scores, of the remaining one or more combinations of solutions.

The generator 142 calculates, for each of the pieces of planting design information thus obtained, each of the effects (the comfort effect, the fatigue relaxation effect, and the impression effect) by using a corresponding one of the pieces of planting design information and Expressions 1 to 3, thereby generating (acquiring) each of the effects (step S5).

The design information outputter 143 outputs the planting design information (step S6). Specifically, the design information outputter 143 outputs, to the display 13, at least one piece of planting design information of the one or more pieces of planting design information generated by the generator 142. For example, the design information outputter 143 outputs, to the display 13, planting design information, in which difference values of the comfort effect, the fatigue relaxation effect, and the impression effect, which are obtainable from each piece of planting design information, respectively from the comfort target value, the fatigue relaxation target value, and the impression target value are minimum, of the one or more pieces of planting design information.

The effect information outputter 144 outputs the effect information (step S7). Specifically, the effect information outputter 144 outputs, as the effect information to the display 13, information including the comfort effect, the fatigue relaxation effect, and the impression effect obtainable based on the planting design information output from the design information outputter 143.

(4) Advantages

As described above, the spatial design device 10 as the spatial design system 1 of the present embodiment includes the acquirer 141, the generator 142, and the design information outputter 143. The acquirer 141 acquires the layout information on the space in the facility, the environment information on the environment in the space, and the target values of the effects which the person in the space is to obtain from the space design for the space. The generator 142 acquires, based on the layout information, the environment information, and the target values, planting design information on a design for a plant to be arranged in the space. The design information outputter 143 outputs the planting design information.

This configuration outputs the planting design information which is acquired based on the layout information, the environment information, and the target value and which is on a design for a plant to be arranged in the space. Thus, a user can be provided with a plating design according to an effect expected by the user. In other words, the spatial design device 10 is configured to provide a planting design according to an effect expected by a user.

Thus, a user can determine a planting design according to an expected effect without repeatedly performing the planting design according to the expected effect by himself/herself.

(5) Variation

Variations will be described below. Note that the variations described below are applicable accordingly in combination with the embodiment described above.

(5.1) First Variation

In the embodiment described above, the generator 142 may generate (acquire), as the plant species of a plant, constituent element information on the plant. In this case, the design information outputter 143 causes the constituent element information on the plant to be displayed as the plant species by the display 13.

In this case, in Expressions 1 to 3, the variable “X (plant species)” may be replaced with a variable “X (the color of leaves, whether or not the leaves have patterns, the shape of the leaves, the number of colors of the leaves, and whether or not the leaves include at least one accent leaf)”.

(5.2) Second Variation

In the first variation, the design information outputter 143 causes the constituent element information on the plant to be displayed by the display 13, but alternatively, the design information outputter 143 may extract a type of a plant (plant species) associated with constituent element information generated (acquired) by the generator 142 on the plant and cause the plant species thus extracted to be displayed by the display 13. In this case, the generator 142 selects, based on the constituent element information on a plant to be arranged in the space, one type from types of a plurality of plants. The generator 142 generates (acquires) planting design information including, as the plant species, the one type thus selected. For example, the generator 142 selects one plant species of types of a plurality of plants from the storage 11, the one plant species being associated with the constituent element information on a plant to be arranged in the space. The generator 142 generates (acquires) planting design information including the plant species thus selected.

(5.3) Third Variation

In the embodiment described above, the effect information outputter 144 may calculate the comfort effect in accordance with Expression 4 “Y4=a1·Z11 (plant A)+b1·Z12 (plant B)+ . . . +P (X (temperature), X (humidity), X (illuminance))”. In the expression, “a1” is the comfort score associated with a plant A, “b1” is the comfort score associated with a plant B, Z11 (plant A) is a variable for the plant A, and Z12 (plant B) is a variable for the plant B.

The effect information outputter 144 may calculate the fatigue relaxation effect by using Expression 5 “Y5=a2·Z21 (plant A)+b2·Z22 (plant B)+ . . . +P (X (temperature), X (humidity), X (illuminance))”. In the expression, “a2” is the fatigue relaxation score associated with the plant A, “b2” is the fatigue relaxation score associated with the plant B, Z21 (plant A) is a variable for the plant A, and Z22 (plant B) is a variable for the plant B.

The effect information outputter 144 may calculate the impression effect in accordance with Expression 6 “Y6=a3·Z31 (plant A)+b3·Z32 (plant B)+ . . . +P (X (temperature), X (humidity), X (illuminance))”. In the expression, “a3” is the impression score associated with the plant A, “b3” is the impression score associated with the plant B, Z31 (plant A) is a variable for the plant A, and Z32 (plant B) is a variable for the plant B.

(5.4) Fourth Variation

In the embodiment described above, the planting design information includes the arrangement and the amount of a plant and a plant species, but the panting design information is not limited to this example.

The planting design information may include one or two of the arrangement and the amount of the plant and the plant species. That is, the planting design information may include at least one of the arrangement and the amount of the plant and the plant species.

(5.5) Fifth Variation

In the embodiment described above, the spatial design device 10 is configured to acquire the comfort effect, the fatigue relaxation effect, and the impression effect as the effects which a person in the space obtains, but the spatial design device 10 is not limited to this example.

The spatial design device 10 may acquire one or two effects of the comfort effect, the fatigue relaxation effect, and the impression effect as the effect(s) which a person in the space obtains. That is, the spatial design device 10 is at least configured to acquire at least one effect of the comfort effect, the fatigue relaxation effect, or the impression effect as the effect which a person in the space obtains.

In this case, the effect information includes at least one effect of the comfort effect, the fatigue relaxation effect, and the impression effect acquired by (the generator 142 of) the spatial design device 10.

(5.6) Sixth Variation

In the embodiment described above, the temperature information included in the environment information in the spatial design device 10 is a temperature set in the space of the facility, but the temperature information is not limited to this example. The temperature information may be the range of a temperature which can be set in the space of the facility.

Similarly, the humidity information may be the range of a humidity which can be set in the space of the facility. The light information may be the range of illuminance or the range of quantity of light which can be set in the space of the facility. The sound information may be the range of a sound volume allowable in the space of the facility. Note that the environment information may include both the range of illuminance and the range of the quantity of light as the light information.

(5.7) Seventh Variation

In the embodiment described above, the design information outputter 143 is configured to output, to the display 13, planting design information, in which difference values of the comfort effect, the fatigue relaxation effect, and the impression effect, which are obtainable from each piece of planting design information, respectively from the comfort target value, the fatigue relaxation target value, and the impression target value are minimum, of the one or more pieces of planting design information. However, this should not be construed as limiting.

The design information outputter 143 may output, to the display 13, planting design information, in which an average value (first average value) of the comfort effect, the fatigue relaxation effect, and the impression effect obtainable from each piece of planting design information is equal to, or is closest to, an average value (second average value) of the comfort target value, the fatigue relaxation target value, and the impression target value, of the one or more pieces of planting design information. Note that if the one or more pieces of planting design information include a plurality of pieces of planting design information in which the first average value is equal to, or is closest to, the second average value, all of the plurality of pieces of planting design information in which the first average value is equal to, or is closest to, the second average value are output to the display 13.

Alternatively, the design information outputter 143 may output, to the display 13, a prescribed number of pieces of planting design information in descending order of degree of equality of the first average value and the second average value of the one or more pieces of planting design information.

(5.8) Eighth Variation

In the embodiment described above, the effect information outputter 144 is configured to quantify each of the comfort effect, the fatigue relaxation effect, and the impression effect and cause each of these quantified effects to be displayed by the display 13, but the effect information outputter 144 is not limited to this example.

The effect information outputter 144 may be configured to express a numerical value of each of the comfort effect, the fatigue relaxation effect, and the impression effect in color and cause each of these effects expressed in color to be displayed by the display 13. In sum, the effect information outputter 144 is at least configured to output visualized information on each of the comfort effect, the fatigue relaxation effect, and the impression effect visually perceivable by a user.

(5.9) Ninth Variation

In the embodiment described above, the design information outputter 143 is configured to cause a screen (first screen) based on the planting design information to be displayed by the display 13 but is not limited to this example.

The design information outputter 143 may cause the first screen to be displayed by another terminal (e.g., an information appliance such as a tablet computer or a smartphone) by communication such as wireless communication.

Similarly, the effect information outputter 144 may cause a screen (second screen) based on the effect information to be displayed by another terminal (e.g., an information appliance such as a tablet computer or a smartphone) by communication such as wireless communication.

(5.10) Tenth Variation

In the embodiment described above, acquisition order of the target values (the comfort target value, the fatigue relaxation target value, and the impression target value), the environment information, and the layout information acquired by the acquirer 141 is not limited to the order shown in steps S1 to S3 in FIG. 2. The acquisition order of the target values (the comfort target value, the fatigue relaxation target value, and the impression target value), the environment information, and the layout information is not particularly limited as long as they are acquired prior to step S4.

(5.11) Eleventh Variation

In the embodiment described above, the generator 142 is configured as follows. That is, when regarding the variable “X (arrangement)” of each combination thus calculated, a difference of the distance between the person and the plant from the distance between the location of the person and the planned plant-arrangement location included in the layout information is a prescribed value or greater, the generator 142 excludes such a combination from the combinations of solutions. However, this configuration is not an essential configuration.

The generator 142 does not have to calculate, regarding the variable “X (arrangement)”, the difference of the distance between the person and the plant from the distance between the location of the person and the planned plant-arrangement location included in the layout information. That is, the generator 142 does not have to exclude some of combinations thus calculated.

Similarly, the generator 142 is configured to compare each target value with a corresponding one of the scores. However, this configuration is not an essential configuration. When the generator 142 excludes, based on the distance between the person and the plant, some of the combinations, the generator 142 generates (acquires) each of the remaining combinations as the planting design information. When the generator 142 does not exclude, based on the distance between the person and the plant, some of the combinations, the generator 142 generates (acquires) each of the calculated combinations as the planting design information.

(5.12) Twelfth Variation

In the embodiment described above, the storage 11 is configured to store the feature amount data pieces according to effects which the person in the space is to obtain from the space for each of the types of the plants, but the storage 11 is not limited to this example.

The storage 11 may store the feature amount data pieces according to effects which the person in the space is to obtain from the space for each of constituent elements constituting a corresponding one of plants. The generator 142 generates planting design information on a plant corresponding to a feature amount data piece complying with the target value of the feature amount data pieces for each of the constituent elements constituting the plant.

Alternatively, the storage 11 may store the feature amount data pieces according to effects which the person in the space is to obtain from the space for each of the types of the plants and for each constituent element of the plant.

That is, the storage 11 may store a feature amount data piece according to effects which the person in the space is to obtain from the space for each of the types of the plants and/or for each of the constituent elements constituting the plant.

(Other Variations)

The embodiment is a mere example of various embodiments of the present disclosure. Various modifications may be made depending on design and the like as long as the object of the present disclosure is achieved. Moreover, functions similar to those of the spatial design system 1 may be implemented by, for example, a spatial design method, a computer program, or a non-transitory recording medium in which a program is stored. The spatial design method according to an aspect includes a first acquisition step, a second acquisition step, and a design information output step. The first acquisition step includes acquiring layout information on a space in a facility, environment information on an environment in the space, and a target value of an effect which a person in the space is to obtain from a space design for the space. The second acquisition step includes generating (acquiring), based on the layout information, the environment information, and the target value, planting design information on a design for a plant to be arranged in the space. The design information output step includes outputting the planting design information. A program according to an aspect is a program configured to cause a computer system to function as the spatial design method described above.

The spatial design system 1 according to the present disclosure includes a computer system. The computer system includes a processor and memory as hardware as main components. The processor executes a program stored in the memory of the computer system, thereby implementing the function as the spatial design system 1 of the present disclosure. The program may be stored in the memory of the computer system in advance, may be provided over a telecommunications network, or may be provided as a non-transitory recording medium such as a memory card, an optical disc, or hard disk drive which stores the program and which is readable by the computer system. The processor of the computer system may be implemented as a single or a plurality of electronic circuits including a semiconductor integrated circuit (IC) or a large-scale integrated circuit (LSI). As used herein, the “integrated circuit” such as an IC or an LSI is called by a different name depending on the degree of integration thereof. Examples of the integrated circuits include a system LSI, a very large-scale integrated circuit (VLSI), and an ultra large-scale integrated circuit (ULSI). Optionally, a field-programmable gate array (FPGA) to be programmed after an LSI has been fabricated or a reconfigurable logic device allowing the connections or circuit sections inside of an LSI to be reconfigured may also be adopted as the processor. Those electronic circuits may be either integrated together on a single chip or distributed on multiple chips, whichever is appropriate. The plurality of chips may be collected in one device or may be distributed in a plurality of devices. As mentioned herein, the computer system includes a microcontroller including one or more processors and one or more memories. Thus, the microcontroller also includes one or more electronic circuits including a semiconductor integrated circuit or a large-scale integrated circuit.

Collecting the plurality of functions in the spatial design system 1 in one housing is not an essential configuration of the spatial design system 1. The constituent elements of the spatial design system 1 may be distributed in a plurality of housings. Moreover, at least some functions of the spatial design system 1, for example, some functions of the spatial design device 10 or the like, may be implemented by cloud (cloud computing) or the like.

(Summary)

As described above, a spatial design system (1) of a first aspect includes an acquirer (141), a generator (142), and a design information outputter (143). The acquirer (141) is configured to acquire layout information on a space in a facility, environment information on an environment in the space, and a target value of an effect which a person in the space is to obtain from a space design for the space. The generator (142) is configured to generate, based on the layout information, the environment information, and the target value, planting design information on a design for a plant to be arranged in the space. The design information outputter (143) is configured to output the planting design information.

This configuration provides a planting design from which a user can obtain an effect expected by the user. In other words, a user can be provided with a planting design from which the user can obtain an effect expected by the user.

In a spatial design system (1) of a second aspect referring to the first aspect, the planting design information includes at least one of an arrangement of the plant, an amount of the plant, and a plant species in the space.

With this configuration, a user can know, as the planting design information from which the user can obtain an effect expected by the user, at least one of the arrangement of the plant, the amount of the plant, and the plant species in the space.

In a spatial design system (1) of a third aspect referring to the second aspect, the planting design information includes, as the plant species, constituent element information on constituent elements of the plant to be arranged in the space.

With this configuration, a user can know, as the planting design information from which the user can obtain an effect expected by the user, the constituent element information on the constituent elements of the plant to be arranged in the space.

In a spatial design system (1) of a fourth aspect referring to the second aspect, the generator (142) is configured to select, based on constituent element information on constituent elements of the plant to be arranged in the space, one plant species from types of a plurality of plants. The generator (142) is configured to generate the planting design information including, as the plant species, the one plant species thus selected.

With this configuration, the type of the plant is acquired based on the constituent element information.

A spatial design system (1) of a fifth aspect referring to any one of the first to fourth aspects further includes an effect information outputter (144). The effect information outputter (144) is configured to output, based on the planting design information, effect information on an effect which the person in the space is to obtain from the space.

With this configuration, a user can obtain the effect information. Thus, the user can know a difference between an effect according to the target value and an effect obtainable from the effect information by comparing the effect according to the target value and the effect obtainable from the effect information with each other.

In a spatial design system (1) of a sixth aspect referring to the fifth aspect, the effect information includes at least one of a comfortableness effect in the space, a fatigue relaxation effect in the space, or an impression effect about the space.

With this configuration, a user can know, as an effect obtainable from the planting design, at least one of the comfortableness effect, the fatigue relaxation effect, or the impression effect.

In a spatial design system (1) of a seventh aspect referring to any one of the first to sixth aspects, the environment information includes at least one of temperature information on temperature, humidity information on humidity, light information on light, or sound information on sound in the space

With this configuration, at least one of the temperature information, the humidity information, the light information, or the sound information is used to acquire the planting design information.

A spatial design system (1) of an eighth aspect referring to any one of the first to seventh aspects further includes a storage (11). The storage (11) configured to store feature amount data pieces for each of types of plants and/or for each of constituent elements of the plants, the feature amount data pieces corresponding to effects which the person in the space is to obtain. The generator (142) is configured to generate the planting design information on the plant corresponding to a feature amount data piece complying with the target value of the feature amount data pieces.

With this configuration, the feature amount data piece is used to acquire the planting design information.

A spatial design method of a ninth aspect includes a first acquisition step, a second acquisition step, and a design information output step. The first acquisition step includes acquiring layout information on a space in a facility, environment information on an environment in the space, and a target value of an effect which a person in the space is to obtain from a space design for the space. The second acquisition step includes generating, based on the layout information, the environment information, and the target value, planting design information on a design for a plant to be arranged in the space. The design information output step includes outputting the planting design information.

This spatial design method provides a planting design from which a user can obtain an effect expected by the user. In other words, a user can be provided with a planting design from which the user can obtain an effect expected by the user.

A program of a tenth aspect is a program configured to cause a computer to execute the spatial design method of the ninth aspect.

This program provides a planting design from which a user can obtain an effect expected by the user. In other words, a user can be provided with a planting design from which the user can obtain an effect expected by the user.

### REFERENCE SIGNS LIST

1 Spatial Design System

10 Spatial Design Device

11 Storage

141 Acquirer

142 Generator

143 Design Information Outputter

144 Effect Information Outputter

1. A spatial design system comprising:
an acquirer configured to acquire
layout information on a space in a facility
environment information on an environment in the space, and
a target value of an effect which a person in the space is to obtain from a space design for the space;
a generator configured to generate, based on the layout information, the environment information, and the target value, planting design information on a design for a plant to be arranged in the space; and
a design information outputter configured to output the planting design information.

2. The spatial design system of claim 1, wherein
the planting design information includes at least one of an arrangement of the plant, an amount of the plant, and a plant species in the space.

3. The spatial design system of claim 2, wherein
the planting design information includes, as the plant species, constituent element information on constituent elements of the plant to be arranged in the space.

4. The spatial design system of claim 2, wherein
the generator is configured to
select, based on constituent element information on constituent elements of the plant to be arranged in the space, one plant species from types of a plurality of plants, and
generate the planting design information including, as the plant species, the one plant species thus selected.

5. The spatial design system of claim 1, further comprising an effect information outputter configured to output, based on the planting design information, effect information on an effect which a person in the space is to obtain from the space.

6. The spatial design system of claim 5, wherein
the effect information includes at least one of a comfortableness effect in the space, a fatigue relaxation effect in the space, or an impression effect about the space.

7. The spatial design system of claim 1, wherein
the environment information includes at least one of temperature information on temperature, humidity information on humidity, light information on light, or sound information on sound in the space.

8. The spatial design system of claim 1, further comprising a storage configured to store feature amount data pieces for each of types of plants and/or for each of constituent elements of the plants, the feature amount data pieces corresponding to effects which the person in the space is to obtain, wherein
the generator is configured to generate the planting design information on the plant corresponding to a feature amount data piece complying with the target value of the feature amount data pieces.

9. A spatial design method comprising:
a first acquisition step of acquiring layout information on a space in a facility, environment information on an environment in the space, and a target value of an effect which a person in the space is to obtain from a space design for the space;
a second acquisition step of generating, based on the layout information, the environment information, and the target value, planting design information on a design for a plant to be arranged in the space; and
an output design information output step of outputting the planting design information.

10. A non-transitory computer-readable tangible recording medium storing a program configured to cause a computer to execute the spatial design method of claim 9.
